(19) United States
(12) Patent Application Publication
(10) Pub. No.: US 2025/0254824 A1
(43) Pub. Date: Aug. 7, 2025

(54) Reservoir with Flow Tunnel for All-In-One Cooling Systems

(71) Applicant: JetCool Technologies Inc., Littleton, MA (US)

(72) Inventors: Daniel SWEENEY, Littleton, MA (US); Alaina Schiano, Littleton, MA (US); Brian Hill, Littleton, MA (US); Joe Koelle, Littleton, MA (US); Ludwig C. Haber, Littleton, MA (US)

(73) Assignee: JetCool Technologies Inc., Littleton, MA (US)

(21) Appl. No.: 18/430,167

(22) Filed: Feb. 1, 2024

(51) Int. Cl. H05K 7/20; F28F 13/12

(52) U.S. Cl. CPC H05K 7/20272; F28F 13/125; H05K 7/20763

(57) ABSTRACT

Embodiments of the present invention provide a reservoir with a flow tunnel for AIO cooling systems. The flow tunnel inside the reservoir is configured to reduce turbulence and air entrainment at the air-coolant interface (ACI) inside an internal chamber of the reservoir body, which maximizes the volume of liquid coolant fluid that is available to be pumped from the reservoir to a fluidly connected cooling module in the closed loop of an all-in-one (AIO) cooling system combatting fluid loss from permeation and transpiration that may occur in the closed loop cooling system, and limits pressure excursions that might otherwise occur in the closed loop through volumetric expansion of the liquid coolant fluid as the temperatures of the AIO system rise from ambient to normal operating temperatures.

### FIELD OF THE INVENTION

The present invention relates generally to the field of liquid cooling systems for high-performance computing (HPC), semiconductors, servers and data centers, and more particularly to reservoirs for such liquid cooling systems.

### RELATED ART

A “server” is a computer program or device that provides a service to another computer program and its user, also known as the client. In a data center, the physical computer that a server program runs on is also frequently referred to as a server. That physical machine might be a dedicated server, or it might be used for other purposes. A server rack (or “server cabinet”) in a data center is a specialized enclosure designed to hold vertical “stacks” of servers and other information technology (IT) equipment, uninterruptable power supplies (UPS's), storage devices, switches, and other data processing devices. Thus, a server rack provides a compact, secure and organized environment for housing servers and other data processing equipment in a data center.

Modern servers and other high-performance data processing devices and equipment found in data centers typically comprise an enormous number of densely packed, high-performance, heat-generating electronic components, which together generate a considerable amount heat during operation. The generated heat can significantly reduce component performance and shorten the lifespans of the servers and other IT equipment in the server rack. Therefore, in order to keep the servers in a data center operating at peak performance, and reduce the possibility of catastrophic failure during critical computing operations, computer equipment manufacturers and users have introduced air-and liquid-based cooling products and techniques designed to constantly remove excess heat while the servers are running.

Conventional liquid cooling systems for servers and server racks typically require a significant investment in facility level infrastructure to manage and remove enough heat from servers and server racks to help ensure continued high-performance operation of rack-mounted servers. Such facility level infrastructure may consume a considerable amount of physical space within a typical server rack or a typical data center; and this is space that might otherwise be used for additional data processing equipment and increased computing capacity.

To address this problem, Jetcool Technologies LLC (jetcool.com) of Littleton, Massachusetts, USA, provides an all-in-one (AIO) cooling system solution, known as the SmartPlate™ System, in which all the liquid cooling components (e.g., the liquid reservoir, the cooling module, pump, radiator, and conduits) are located in the server instead of being attached to the rack. Although the Jetcool SPS system has generated unprecedented demand from the data center industry, AIO systems more generally have not typically seen broad adoption due to both real and perceived issues in reliability and longevity. Reliability can be addressed in a number of different ways. But lack of longevity is a key limitation keeping AIO systems from broader adoption.

An AIO cooling system is a closed loop cooling system. The closed loop cooling system typically comprises coolant fluid, at least one cooling module, at least one reservoir (sometimes referred to as a “tank”), a heat exchanger (e.g., a radiator), a pump, and a collection of interconnected hoses and manifolds. The cooling module, reservoir, heat exchanger, pump and hoses are all connected together to create the closed loop cooling system in which the coolant fluid circulates, driven by the action of the pump. And, despite the fact that closed loop cooling systems generally aren't known for springing leaks, long term processes such as permeation and vapor transpiration at interfaces between these components tend to limit the lifespan of the closed loop cooling system or require significant periodic maintenance. For systems used by hobbyists, the increased maintenance requirements and reduced lifespans are compromises this market segment may be willing to accept. But such compromises are not acceptable for large and/or expensive data center operations and, therefore, limit broader adoption in business, financial and scientific applications.

The reservoir in an AIO cooling system includes an internal chamber that is configured to temporarily hold liquid coolant fluid that is about to be pumped out of the internal chamber, through one or more hoses and potentially other devices (e.g. radiator) and then into an inlet on the cooling module. The cooling module is attached to a substrate (e.g., a motherboard, a system board, main circuit board, main board, etc.) on the same server as the reservoir. The substrate contains one or more heat-generating, high-powered electronic computing devices, such as, for example, a computer processing unit (CPU), a graphical processing unit (GPU), field programmable gate array (FPGA) or an application-specific integrated circuit (ASIC). The inlet on the cooling module is fluidly connected to internal structures inside the cooling module (such as manifolds, plenums, microjet nozzle plates, nozzles, walls and flanges, for example) that together cooperate to direct the liquid coolant fluid to remove heat from the cooling surface that is in thermal communication with one or more of the heat-generating, high-powered electronic devices to be cooled.

When the liquid coolant fluid interacts with the cooling surface, heat that has been transferred from the heat-generating device to the cooling surface by conductive heat transfer is rapidly transferred to the liquid cooling fluid via convective heat transfer. As the liquid coolant fluid absorbs heat from the cooling surface, the liquid coolant fluid is warmed up. The now warmed up liquid coolant fluid is then forced by the action of the pump to flow out of the cooling module, and recirculate through the hoses and other devices (e.g. radiator), where it will be re-cooled before circulating back to the reservoir to begin another cooling cycle. The order of components (cooling module, reservoir, radiator) within the cooling system typically represents a design preference and components are arranged in different order depending on a number of factors, including simple aesthetic preference based on a the layout in a given server.

Notably, when the server is in operation, the heat absorbed by the liquid coolant fluid as it passes over the cooling surface causes the internal temperature of the liquid coolant fluid to rise. This rise in temperature causes the liquid coolant fluid inside the closed loop cooling system to expand. When the liquid coolant fluid begins to expand, there must be a sufficient amount of space inside the closed loop cooling system to accommodate the expansion. To provide the necessary space for the expansion of the liquid coolant fluid, in addition to holding the required amount of liquid coolant fluid, the closed loop also must hold some volume of compressible air (or some other compressible gas) so that when the rising operating temperature of the system causes the liquid coolant to expand, the small volume of air (or other gas) in the closed loop cooling system is compressed, thereby creating enough space in the closed loop cooling system to hold both the warmed and expanded liquid coolant fluid and the compressed air, without causing significant increases in the internal pressure of the closed loop cooling system. So the presence of a compressible gas inside the closed loop of the AIO coolant system reduces the peak internal pressure able to be generated during the coolant warmup, and helps protect its overall integrity, by significantly reducing the risk that the internal pressures experienced inside the closed loop cooling system due to expansion of the liquid coolant fluid will exceed the maximum operating pressure of one or more components in the closed loop cooling system and thereby cause one or more components in the closed loop cooling system to leak.

Unfortunately, ensuring that there is a sufficient amount of air inside the closed loop cooling system to accommodate the potential maximum thermal expansion of the liquid coolant fluid inside the closed loop cooling system creates a problem. Namely, all or most of the air inside the closed loop cooling system may collect, and usually does collect, at a single location inside the closed loop cooling system, thereby creating a pocket of air somewhere within the closed loop cooling system. If a pocket of air does develop inside the closed loop cooling system, it will predominately develop at a location in the closed loop cooling system where the liquid coolant fluid is at its lowest velocity, which is, by definition, inside the internal chamber of the reservoir.

The boundary between the liquid coolant fluid and the pocket of air inside the internal chamber of the reservoir, referred to as the air-coolant interface (ACI), can be, and usually will be, subjected to some degree of turbulence. This turbulence is caused by the dissipation of fluid momentum from the flow entering the reservoir. The transfer of momentum between the incoming flow and turbulence can occur as the inlet flow strikes internal boundaries of the tank. The turbulence tends to create bubbles at the ACI. When the liquid coolant fluid is forced by action of the pump to flow out of the internal chamber of the reservoir and into the cooling module, the flow of liquid coolant fluid passing through the internal chamber can entrain some of the air in the form of the bubbles located at the ACI. This entrainment of air and air bubbles can lead to a significant degradation in the overall performance of the AIO coolant system because less liquid coolant fluid is available to flow into the cooling module and be directed to provide convective cooling at the cooling surface in thermal communication with the heat-generating electronic devices on the server, which results in less effective cooling. Even in the case where the cooling system is designed and liquid filled in such a way as to try to avoid creating the ACI during system startup, the potential loss of liquid coolant fluid over time (through unavoidable permeation and transpiration of components in the closed loop cooling system) and corresponding gaseous intrusion into the closed loop cooling system can, and often does, lead to the eventual development of an ACI with the likelihood that turbulence within the reservoir will cause ongoing entrainment of air from the ACI to reduce system performance. The result is that existing AIO systems are significantly challenged by both 1) limited lifespans due to unavoidable slow permeation and transpiration, and 2) potentially significant performance degradation caused by air and bubble entrainment at the ACI of the reservoir.

Accordingly, there is considerable need in the art for AIO cooling systems that are capable of increasing the available volume of liquid coolant fluid despite inevitable losses due to permeation and transpiration, while simultaneously reducing the likelihood of air entrainment at the ACI inside the internal chamber of the reservoir. There is a further need in the art to provide reservoirs for AIO systems capable of maintaining relatively smaller isolated air pockets to limit pressure excursions due to volumetric expansion of the liquid coolant fluid as the liquid cooling system transitions from ambient temperatures to normal operating temperatures.

### SUMMARY OF THE INVENTION

Embodiments of the present invention provide a fluid reservoir for an AIO closed loop cooling system. The fluid reservoir includes a novel flow tunnel for the liquid coolant fluid to pass through before flowing out of the reservoir and on to the other components of the AIO closed loop cooling system. The flow tunnel is configured to reduce turbulence and air entrainment at the air-coolant interface (ACI) inside an internal chamber of the fluid reservoir. In a AIO closed loop system comprising a reservoir, a cooling module, a heat exchanger and a pump, installing a reservoir of the present invention, which is equipped with the specialized flow tunnel, the flow tunnel reduces turbulence and air entrainment in the reservoir, and maximizes the volume of liquid coolant fluid that can be lost via permeation or transpiration before system failure, therefore maximizing system lifetime. The reservoir, and more specifically, the flow tunnel inside the reservoir, also limits pressure excursions that might otherwise occur in the closed loop cooling system, due to volumetric expansion of the liquid coolant fluid as the temperatures of the AIO system rise from ambient to normal operating temperatures.

In some embodiments of the present invention, the reservoir and the flow tunnel may be constructed as a single unit (unitary construction embodiment), in which the flow tunnel is an integral, unremovable and built-in component of the reservoir. In other embodiments, the reservoir and the flow tunnel may be manufactured separately as two (or more) distinct components, each component comprising the necessary fittings so that the flow tunnel component(s) may be permanently or removably inserted into an internal chamber in the body of the reservoir component(s) after all the separate components are manufactured. Accordingly, it should be understood that the benefits and advantages of embodiments of the present invention are achieved primarily by the structure of the flow tunnel residing inside an internal chamber of the reservoir, as will be detailed below, regardless of whether (or not) the flow tunnel is an integral (built-in) part of the reservoir or a separately manufactured insert, although the implementation of the flow tunnel as an insert may provide some potential advantages in terms of ease of manufacture.

In general, reservoirs constructed according to embodiments of the present invention comprise a reservoir body having an inlet and an outlet, a reservoir lid attached to the reservoir body, an internal chamber disposed between the reservoir body and the reservoir lid, and a flow tunnel disposed within the internal chamber. The flow tunnel disposed within the internal chamber comprises an entry port, an exit port, an upper portion proximate to the entry port, a lower portion proximate to the exit port, and an active flow pattern region located between the upper portion and the lower portion and extending from the entry port to the exit port. The inlet on the reservoir is fluidly coupled to the entry port on the flow tunnel so that liquid coolant fluid that flows into the inlet of the reservoir will immediately pass through the entry port and into the active flow pattern region of the flow tunnel. The exit port on the flow tunnel is fluidly coupled to the outlet on the reservoir so that liquid coolant fluid that flows out of the exit port on the flow tunnel will pass through the outlet on the reservoir.

The flow tunnel creates and manages parallel flow paths. The first flow path, flows through an “active flow pattern region” located inside the flow tunnel extending from the entry port to the exit port of the flow tunnel. The second flow path flows through a “passive flow pattern region” located outside, above and around the flow tunnel, but within the internal chamber of the reservoir body. To create the parallel flow paths, the flow tunnel further includes an active to passive flow communication channel located in the upper portion of the flow tunnel and a passive to active flow communication channel located in the lower portion of the flow tunnel. The active to passive flow communication channel on the upper portion of the flow tunnel is configured to cause at least some of the liquid cooling fluid flowing into the active flow pattern region via the entry port to pass out of the active flow pattern region and into a passive flow pattern region of the internal chamber of the reservoir. This causes some small fraction of liquid coolant fluid to be pushed toward the reservoir free surface, if any, existing at top of the internal chamber, while the bulk of the liquid coolant fluid in the active flow pattern region will be pushed towards the exit port and the reservoir outlet.

At the same time, the passive to active flow communication channel on the lower portion is configured to cause at least some of the liquid cooling fluid located inside the passive flow pattern region of the internal chamber to pass out of the passive flow pattern region of the internal chamber and back into the active flow pattern region of the flow tunnel. A descending pressure gradient is created in the active flow pattern region as a result of liquid coolant fluid moving from the entry port to the exit port due to frictional or form losses.

Preferably, the flow tunnel provides a contoured flow path through the internal chamber to help limit pressure drop and turbulence generation. The flow tunnel provides some limited communication between the contoured flow path and the reservoir free surface (reservoir level) without causing air entrainment. High points within the contoured flow path may be created and managed to provide potential air bubbles existing in the bulk recirculating flow a path to the free surface without at the same time causing air to be entrained into the discharging fluid from the reservoir.

By using the flow tunnel to carefully manage the overall pressure drop within the reservoir and generate parallel flow paths within the internal chamber of the reservoir body, embodiments of the present invention minimize the pressure drop across the reservoir, maintaining a certain level of interaction with the reservoir free surface to allow for bubbles to be removed from the recirculation flow stream, and avoiding air entrainment from the free surface. This process helps maximize AIO cooling system lifetimes for a given reservoir footprint.

### BRIEF DESCRIPTION OF THE FIGURES

The accompanying drawings, which are incorporated in and constitute part of the specification, illustrate preferred embodiments of the invention, and, together with the description, serve to explain the principles of the present invention. In the drawings, like reference numbers indicate identical or functionally similar elements. Additionally, the left-most digit(s) of a reference number identifies the drawing in which the reference number first appears.

FIG. 1 shows, by way of example, an exemplary server that may be a suitable target for an AIO cooling system and a reservoir constructed in accordance with certain embodiments of the present invention.

FIG. 2 shows the components of an exemplary AIO cooling system as it might be installed on the circuit board of a server, such as the circuit board of the server depicted in FIG. 1.

FIG. 3 shows an exploded diagram illustrating the primary components of a reservoir constructed and configured to operate in accordance with one exemplary embodiment of the present invention.

FIG. 4 shows a cross-section of a reservoir constructed according to one embodiment of the present invention.

FIGS. 5A and 5B illustrate, by way of example, a few optional features that may be added to flow tunnels inside reservoirs constructed according to certain embodiments of the present invention to further improve performance.

FIG. 6 shows another optional refinement of certain embodiments of the flow tunnel according to the present invention.

### DETAILED DESCRIPTION OF THE PREFERRED EMBODIMENTS

Reference will now be made in detail to the preferred embodiments of the invention, examples of which are illustrated in the accompanying drawings. Notably, the present invention may be implemented using software, hardware or any combination thereof, as would be apparent to those of skill in the art, and the figures and examples below are not meant to limit the scope of the present invention or its embodiments or equivalents.

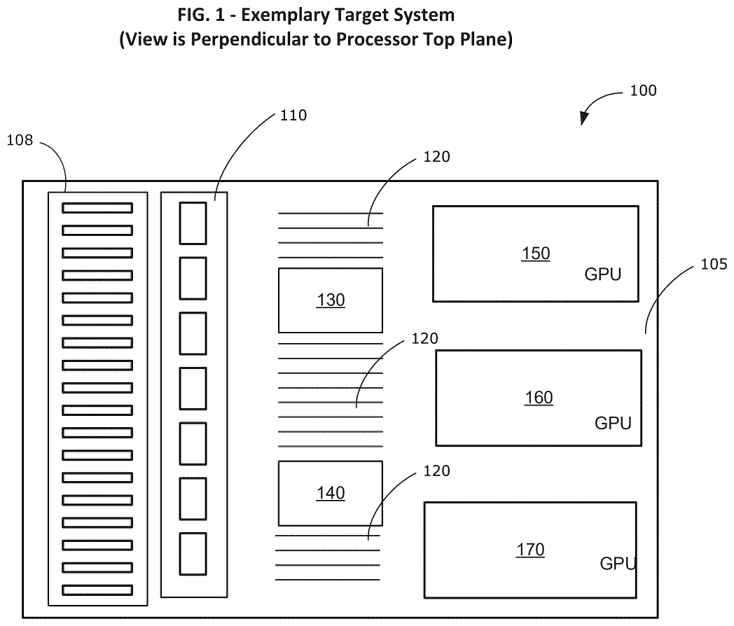

FIG. 1 shows, by way of example, an exemplary server 100 that may be a suitable target for an AIO cooling system and a reservoir constructed in accordance with certain embodiments of the present invention. (Note that the AIO cooling system itself is not shown in FIG. 1). As shown in FIG. 1, the exemplary server 100 comprises a circuit board 105 having a typical layout of electronic components, some of which may comprise high-performance, heat-generating devices that will benefit from cooling by way of liquid cooling technology. In this case, the circuit board 105 of the server 100 carries hard drives 108, multiple random access memory (RAM) modules 120, a pair of central processing units (CPUs) 130 and 140, and three expansion cards 150, 160 and 170. The expansion cards 150, 160 and 170 may comprise, for example, networking cards, graphical processing units (GPUs), etc. The circuit board 105 also carries a set of native server fans 110 that provide air flow for some of the electronic devices on the circuit board 105, such as RAM modules 120. In this example, the heat-generating electronic components that are most likely to be cooled by an AIO cooling system constructed in accordance with embodiments of the present invention include, the pair of CPUs 130 and 140, and the expansion cards 150, 160 and 170.

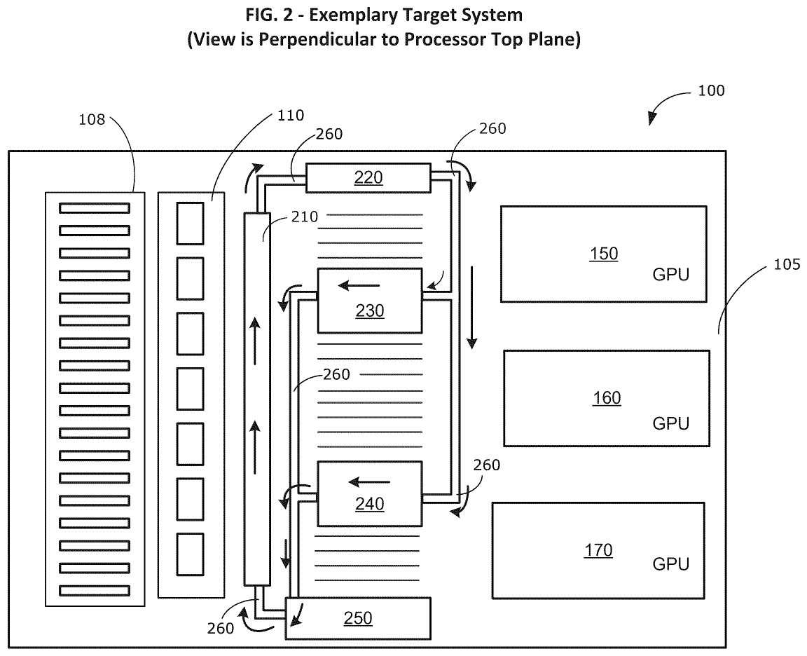

FIG. 2 shows the components of an exemplary AIO cooling system as it might be installed on the circuit board of a server, such as the circuit board 105 of server 100 depicted in FIG. 1, to provide cooling of two of the heat-generating electronic components on that server. As shown in FIG. 2, the AIO cooling system comprises of a pump 250, a radiator 210 (or other heat exchanger), a reservoir 220, a first cooling module 230 attached to the top of the first CPU 130, a second cooling module 240 attached to the top of the second CPU 140, and interconnecting tubing 260, which fluidly connects together all of the aforementioned AIO cooling system components, creating a closed loop cooling system. The order of the components in the closed loop cooling system may be optimized based on a variety of different factors, including, but not limited to, the specific number, geometries and sizes of the components in the closed loop cooling system, the cooling requirements of the particular heat-generating electronic devices on the server 100 that need to be cooled, as well as the specific application to be run on the server 100. Therefore, the exact order of the components in the closed loop cooling system of the AIO cooling system can vary significantly from one server to another, or from one data center to another. In the example shown in FIG. 2, the closed loop cooling system is defined by the interconnected components of the pump 250, the radiator 210, the reservoir 220, the first cooling module 230, the second cooling module 240, and the interconnecting tubing 260. The direction of the flow of liquid coolant fluid around this closed loop cooling system is indicated in FIG. 2 by the flow arrows that are shown adjacent to, or inside, each one of these closed loop cooling system components.

Thus, it may observed that in the exemplary closed loop cooling system of FIG. 2, liquid coolant fluid leaving the first and second cooling modules 230 and 240 via the tubing 260 first flows into and through the pump 250, and then into and through the radiator 210, and then into and through the reservoir 220. Upon leaving the reservoir 220, the interconnected tubing 260, as well as the flow of liquid coolant fluid, “splits” so that some of the liquid coolant fluid passes into and through the first cooling module 230, while the rest of the flow of cooling fluid passes into and through the second cooling module 240. In this manner, the liquid coolant fluid flows around the closed loop cooling system continuously while the server 100 is in operation in order to provide continuous cooling for the CPUs 130 and 140 located beneath the first and second cooling modules 230 and 240, respectively.

It should be understood that additional reservoirs, additional cooling modules and additional sections of interconnected tubing may be added to the closed loop cooling system depicted in FIG. 2 without departing from the intended scope of the invention. Such additional components may be added, for example, to provide continuous liquid cooling to one, two or all of the GPUs 150, 160 and 170.

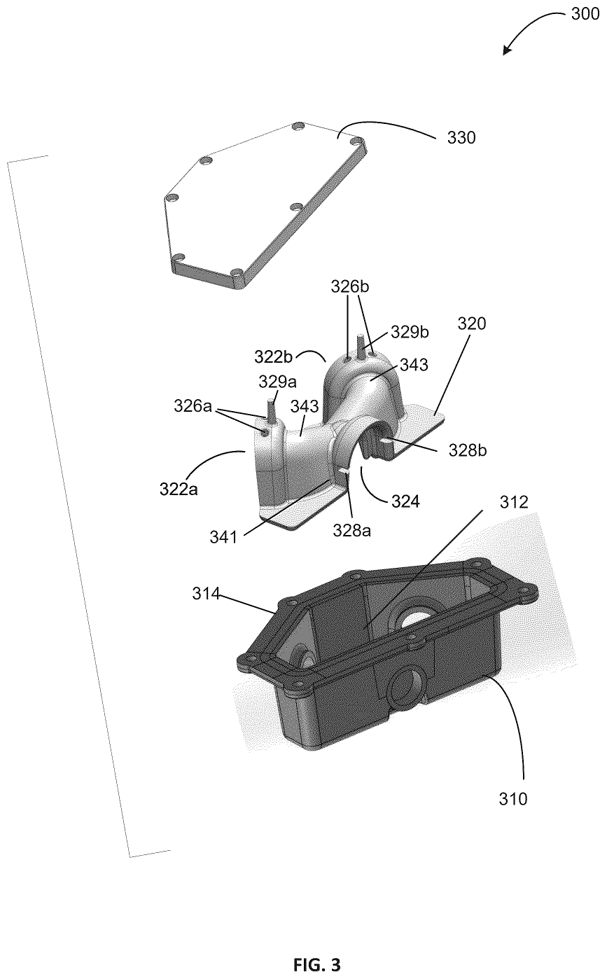

FIG. 3 shows an exploded diagram illustrating an exemplary configuration of a reservoir 300 constructed and configured to operate in accordance with one exemplary embodiment of the present invention. This reservoir 310 could be inserted into the closed loop cooling system in FIG. 2 at the location indicated by reservoir 220, or it could also be placed in an extension (not shown) of the closed loop cooling system of FIG. 2, wherein the extension is designed to provide continuous liquid cooling for one or more of the GPUs 150, 160 and 170. As shown in FIG. 3, the reservoir 300 comprises a reservoir body 310, a flow tunnel 320 configured to fit inside an internal chamber 312 defined by the inner walls of the reservoir body 310, and a reservoir lid 330 configured to be attached to the top 314 of the reservoir body 310. The reservoir lid 330 may be permanently or removably attached to the top 314 of the reservoir body 310 by any suitable fastener or adhesive, including without limitation, screws, bolts, nuts, anchors, pins, clamps, clips, seal, glue or solder, or welding methodology.

The flow tunnel 320 shown in FIG. 3 comprises two entry ports, 322a and 322b, which are fluidly connected to a single exit port 324. It should be understood, however, that other embodiments of the flow tunnel may have a single entry port, and some embodiments may have a plurality or multiplicity of entry ports, as well as two or more exit ports. The entry ports 322a and 322b are each equipped with a pair of active to passive flow communication channels 326a and 326b, respectively, which are located near the upper portions 343 of the flow tunnel 320 to promote a limited amount of flow communication between the active volume of liquid coolant fluid passing through the under-side of the flow tunnel 320 and the more quiescent volume of liquid coolant fluid located outside, above and around the flow tunnel 320. The exit port 324 of the flow tunnel 320 includes a pair of passive to active flow communication channels 328a and 328b. Notably, the passive to active flow communication channels 328a and 328b on the exit port 324 are located on a lower portion 341 of the flow tunnel 320, and therefore will be positioned lower in the fluid column of the internal chamber 312 of the reservoir body 310 (as compared to the active to passive flow communication channels 326a and 326b located on the upper portions 343 of the flow tunnel 320) to reduce the possibility of the passive to active flow communication channels 328a and 328b entraining air from the volume of air that is likely to accumulate near the upper portion 343 of the flow tunnel 320 and the top 314 of the internal chamber 312 of the reservoir body 310 when the server is put into operation. The particular embodiment of the flow tunnel 320 shown in FIG. 3 also includes a pair of standoff pins 329a and 329b to help secure and stabilize the flow tunnel 320 when it is positioned between the reservoir lid 330 and the bottom of the internal chamber of the reservoir body 310. It should be understood, however, that although other stabilizing structures may be used, in addition to, or instead of, the standoff pins 329a and 329b to help stabilize the orientation of the flow tunnel 320 in the internal chamber 312 of the reservoir body 310. As previously stated, flow tunnel 320 may also be built into the internal chamber 312 of the reservoir body 310 at the time that the reservoir body 310 is manufactured.

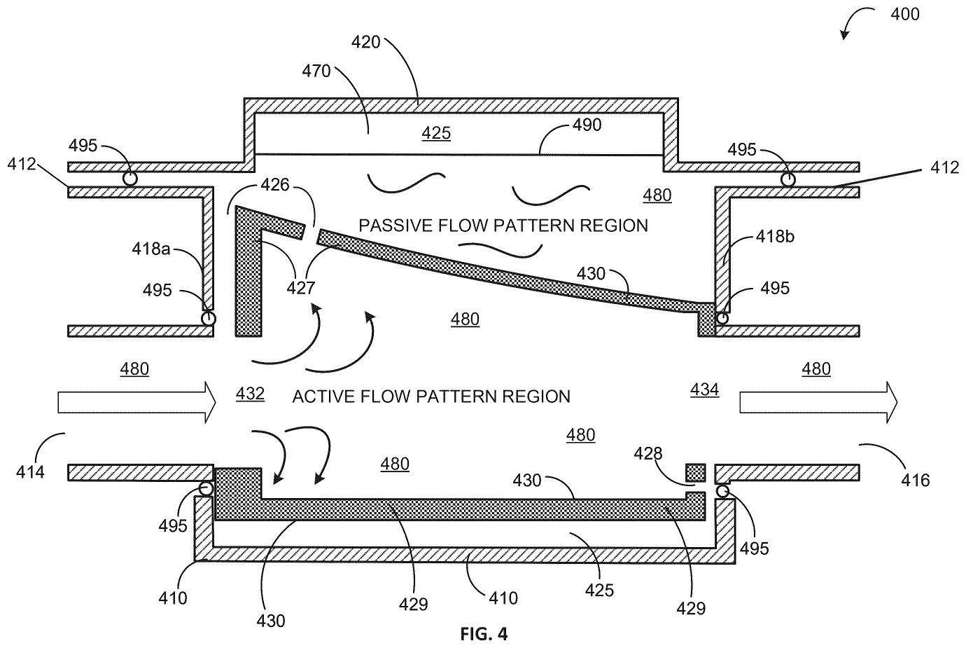

FIG. 4 shows a cross-section of a reservoir 400 constructed according to one embodiment of the present invention. As shown in FIG. 4, the reservoir 400 comprises a reservoir body 410 with a reservoir lid 420 affixed to the top 412 of the reservoir body 410. The side walls 418a and 418b of the reservoir body 410 and the reservoir lid 420 are configured to define an internal chamber 425, an inlet 414 that admits liquid coolant fluid 480 into the internal chamber 425, and an outlet 416 that permits liquid coolant fluid 480 to pass out of the internal chamber 425.

A flow tunnel 430 is positioned inside the internal chamber 425. The flow tunnel 430 may, or may not, be removable from the internal chamber 425 of the reservoir body 410, depending on the method of manufacturing the reservoir 400 and/or the flow tunnel 430. The flow tunnel 430 of the reservoir 400 comprises an entry port 432 and an exit port 434, which are configured to coincide with and/or engage with the inlet 414 and the outlet 416, respectively, of the reservoir body 410, so that any liquid coolant fluid 480 that flows into the reservoir body 410 via the inlet 414 will immediately pass into the flow tunnel 430 via the entry port 432, and any liquid coolant fluid 480 that flows out of the flow tunnel 430 via the exit port 434 will immediately pass through the outlet 416 of the reservoir body 410.

During the operation of the server containing the reservoir 400 depicted in FIG. 4, a volume of air 470 may develop in the internal chamber 425 of the reservoir body 410 due to permeation and transpiration that occurs in the components and the joints of the closed loop cooling system over time. The boundary between the volume of air 470 and the surface of the liquid coolant fluid, referred to as the air to coolant interface (or “ACI) is indicated with the reference number 490 in FIG. 4.

The flow tunnel 430 is configured to generate a pressure gradient inside the flow tunnel 430, such that two flow paths will be created inside the reservoir body 410 along at least a portion of the flow tunnel 430. The first flow path passes through the active flow pattern region, which is located inside the flow tunnel 430, and extends from the entry port 432 to the exit port 434 of the flow tunnel 430. The second flow path passes through the passive flow pattern region, which is located outside, above and around the flow tunnel 430, within the internal chamber 425 of the reservoir body, and extending from the inlet 414 to the outlet 416 of the reservoir 400.

The development of the two flow paths inside the reservoir body 425 and the flow tunnel 430 is enabled by the active to passive flow communication channels 426 on the upper portion 427 of the flow tunnel 430 and the passive to active flow communication channels 428 on the lower portion 429 of the flow tunnel 430. The active to passive flow communication channels 426 permit some of the liquid coolant fluid 480 inside the flow tunnel 430 to pass out of the flow tunnel 430 and into the passive flow pattern region of the internal chamber 425 of the reservoir body 410. At the same time, the passive to active flow communication channels 428 draws some of the liquid coolant fluid 480 located in the passive flow region outside of the flow tunnel 430 back into the flow tunnel 430. As shown, the passive to active flow communication channels 426 are located at a lower position on the flow tunnel 430 than the active to passive flow communication channels so that the drawing of liquid coolant fluid 480 through the passive to active flow communication channels 428 does not entrain any air 470 that may have collected in the top 412 of the internal chamber 425 and under the reservoir lid 420. Typically, the parallel flow paths will be easiest to implement by placing the active to passive flow communication channels 426 near the reservoir inlet(s) 414 of the reservoir body 410 and placing the passive to active flow communication channels 428 near the reservoir outlet(s) 416 of the reservoir body 410, although other locations for the flow communication channels are possible. This is because the flow of coolant 480 between the flow tunnel entrance 432 and the flow tunnel exit 434 will typically create a descending pressure gradient motivating flow to exit the flow communication channels near the inlet (426) from the flow tunnel 430 and at the same time motivating flow to enter the flow communication channels 428 near the exit back into the flow tunnel 430. However, as discussed below under the topic of optional refinements, a diffuser or a converging-diverging shape for the flow tunnel 430 can be used to support locating both active to passive flow communication channels 426 and the passive to active flow communication channels 428 in a variety of different locations along the flow tunnel 430.

FIG. 4 also highlights the possibility of providing an air cushion 470 located above the passive flow pattern region of the internal chamber 425 of the reservoir body 410 to support system compliance and reduce the pressure increase caused by thermal expansion of the liquid coolant fluid 480 when the liquid coolant fluid 480 heats up from ambient temperatures to the operating temperature. In some embodiments where inlet fittings, outlet fittings and the reservoir lid 412 are not permanently attached to the reservoir body 410, these connections require a sealed interface, such as the gaskets and/or O-rings, which are identified with the reference number 495 in FIG. 4.

Embodiments of the present invention provide a variety of valuable benefits, including but not limited to: (1) maximizing the available volume of liquid coolant fluid prior to air entrainment in a given volumetric footprint; (2) reducing the flow losses in the reservoir by maintaining some of the inlet momentum as the flow moves from one or more inlets to one or more outlets within the reservoir; (3) reducing the maximum pressure in the AIO system by providing an air cushion in the reservoir to improve system compliance with specified pressure limitations while simultaneously reducing the interaction between the active flow region of the reservoir and the air cushion; and (4) preventing the formation of flow patterns that might entrain air from the air cushion into the outlet flow.

All of these positive outcomes are achieved by reservoirs with flow tunnels constructed in accordance with the embodiments of the present invention, where the flow tunnel guides liquid coolant fluid from the inlet(s) to the outlet(s) of the reservoir in a more controlled fashion than conventional reservoirs without flow tunnels. By guiding the flows of liquid coolant fluid through the reservoir in a more controlled manner, sudden expansion pressure losses at the inlet(s) side are reduced or eliminated, and contraction pressure losses at the outlet(s) of the reservoir are reduced or eliminated. When a reservoir that lacks a flow tunnel constructed and used in accordance with embodiments of the present invention is used, energy contained in the inlet flow(s) of the reservoir is more likely to dissipate inside the body of the reservoir, which produces pressure losses in the system, potentially disturbs the surface of the liquid coolant fluid at the air-cushion interface of the reservoir, and potentially leads to entraining air from the surface of the liquid coolant fluid. Entrained air in the flow of liquid coolant fluid sent to the cooling module(s) can make the recirculating flows of liquid cooling fluid in the AIO cooling system bubbly, which reduces its cooling performance and risks creating instability in the operation of the pump and reducing the lifespan of the cooling system and/or the heat-generating electronic components to be cooled.

Typically, a certain volume of liquid coolant fluid is required to be in the closed loop cooling system to ensure that the closed loop cooling system remains substantially free of air bubbles, even as some of the liquid coolant fluid is lost to permeation and transpiration. These relatively slow losses of liquid coolant fluid are balanced by gaseous intrusion from the ambient atmosphere, typically in the form of air entering into the closed loop cooling system. Over time, it is therefore necessary to expel gases from the general recirculating flow stream within the AIO cooling system and entrain new liquid into the flow stream. The active to passive flow communication channels 426 and the passive to active flow communication channels 428 facilitate this exchange by allowing a small portion of liquid coolant fluid in the active flow pattern region to communicate with the liquid coolant fluid in the passive flow pattern region of the reservoir (outside the flow tunnel 430) without significantly disturbing the free surface of the liquid coolant fluid in the passive flow pattern region generally above the flow tunnel 430. The pressure required to motivate a portion of liquid coolant fluid to pass out of the active flow pattern region and into the passive flow pattern region via the active to passive flow communication channel is generated by the pressure losses that remain as liquid coolant fluid flows through the flow tunnel 430. Similarly, the pressure losses created by the flow tunnel 430 also create a low pressure region near the outlet(s) 416 of the reservoir body 410 so that a small amount of liquid coolant fluid can be drawn into the outlet(s) 416 of the reservoir body 410 via the passive to active flow communication channels 428 of the flow tunnel 430.

To maintain equilibrium, the liquid coolant fluid 480 discharged from the flow tunnel 430 through the active to passive flow communication channel 426 at the inlet(s) 414 and liquid coolant fluid 480 being entrained through the passive to active flow communication channel near the outlet(s) of the reservoir body 410 are equal at all times. Since the volume of liquid coolant fluid 480 outside the flow tunnel 430 is relatively large compared to the small flow rates being supplied to and drawn from the volume outside the flow tunnel 430, the residence time of liquid coolant fluid being returned to the volume outside the flow tunnel 430 is sufficiently long to allow even relatively small bubbles to rise to the free surface of liquid coolant fluid in the reservoir body 410, where the gas will remain isolated from the main loop flow. Since the entrainment of air into the system is a very slow process, the efficiency of bubble removal need not be very high for the closed loop cooling system to remain substantially and functionally free of air bubbles. The presence of the active to passive flow communication channels 426 and the passive to active flow communication channels 428 in the flow tunnel 430 provides the residence time within the reservoir body 410 to generally prevent any air bubbles that are expelled via the small flow stream from being re-entrained at the outlet(s) 416 of the reservoir body 410.

Locating the active to passive flow communication channels 426 and the passive to active flow communication channels 428 in separated flow regions, and placing the active to passive flow communication channels 426 generally near the top of the inlet(s) 414 of the reservoir body 410 also aid in promoting air bubble transfer out of the main flow stream passing through the reservoir. Preferably, the sizes of the active to passive flow communication channels 426 near entry port(s) 432 of the flow tunnel 410 are carefully optimized so that channels will not be so small that they will prevent large bubbles from leaving the main flow stream through surface tension effects, while not allowing the flow through the active to passive flow channels 426 to have too much momentum to then interact with the free surface 490 within the passive flow pattern region. On the discharge side, the sizes of the passive to active flow communication channels 428 are carefully optimized to delay the onset of air entrainment from the free surface at the outlet(s) 416 as the volume of liquid coolant fluid 480 in the reservoir body 410 drops over time due to fluid loss (permeation, transpiration, etc.). Generally, the passive to active flow communication channels 428 on the discharge side should be located at elevations below the top of the reservoir outlet penetration to delay the onset of air entrainment as much as possible.

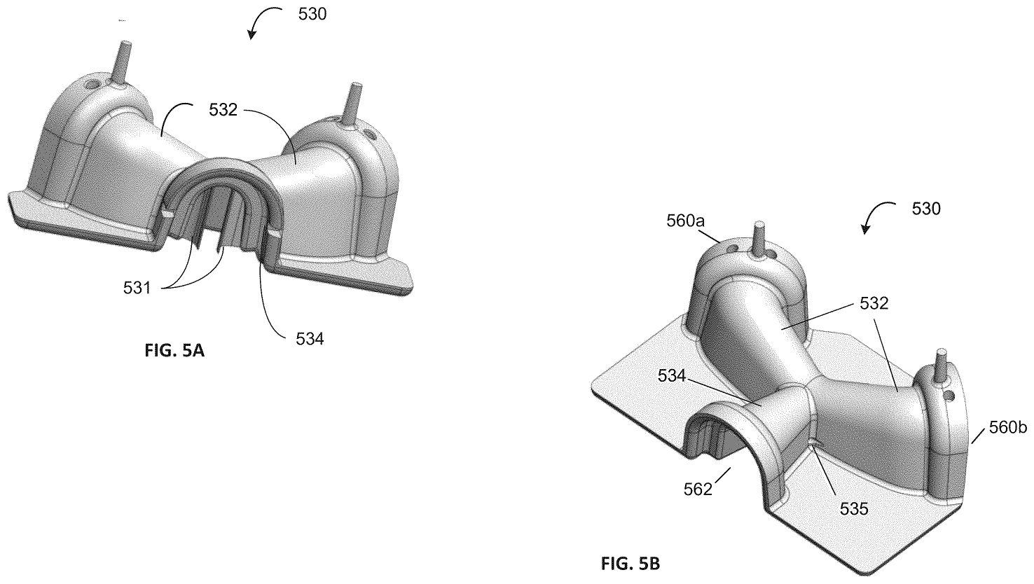

FIGS. 5A and 5B illustrate, by way of example, a few optional features that may be added to flow tunnels inside reservoirs constructed according to certain embodiments of the present invention to further improve performance. FIG. 5A shows the addition of vanes 531 to the flow tunnel 530, near the exit 534 of the flow tunnel 530. The vanes 531 help reduce pressure drop in cases where a smooth turn within the flow tunnel 530 is not possible due, for example, to space constraints.

A further optional refinement of the flow tunnel can be implemented by constructing converging-diverging geometries along the flow tunnel 530, here shown for the entry ports 532 (converging) and the exit port 534 (diffusing) on the flow tunnel 530 to generate particularly low static pressures within the flow tunnel 530 at location 535. These low pressures can be used to connect particularly small flow communication channels between the quiescent bulk reservoir volume and the through-flow inside the flow tunnel 530. These small flow communication channels can further delay the onset of air entrainment by being located particularly low in the reservoir elevation. Contouring of the internal walls of the flow tunnel will help keep pressure losses within the reservoir to an acceptably low level. FIG. 5B shows an implementation of a flow tunnel 530, wherein the entry ports 532 converge and the exit port 534 diverges (diffuses). FIG. 5B also shows the feature of having the active to passive flow communication channel 535, which draws in liquid coolant fluid from the surrounding internal chamber of the reservoir, at the junction of entry ports 532 and the exit port 534, which is the location on the flow tunnel 530 where the lowest pressure is expected to exist. Notably, the active to passive flow communication channel 535 is located in the lower portion of the flow tunnel 530 to help put maximum distance between the active to passive flow communication channel 535 and the surface of the liquid coolant fluid, if any, that may exist inside the reservoir body. As shown best in FIG. 5B, the walls of the entry ports 532 are curved so that the active flow pattern regions extending from the mouths 560a and 560b of the entry ports 532 to the discharge end 562 of the exit port 532 create a contoured flow path for the liquid coolant fluid that flows through the active flow pattern region. The contoured flow path serves reduce pressure losses that might otherwise develop inside the active flow regions of the entry ports 532. The implementation of a diverging flow passage near the exit 562 of the flow tunnel 530 helps to aid in reducing losses by carefully reducing the coolant flow velocity prior to flow exiting the flow tunnel 530. The same technique may also be used at the inlet passages 532 in some embodiments of the invention to reduce the velocity of the coolant flow upon entering the flow tunnel, thereby helping to reduce pressure losses.

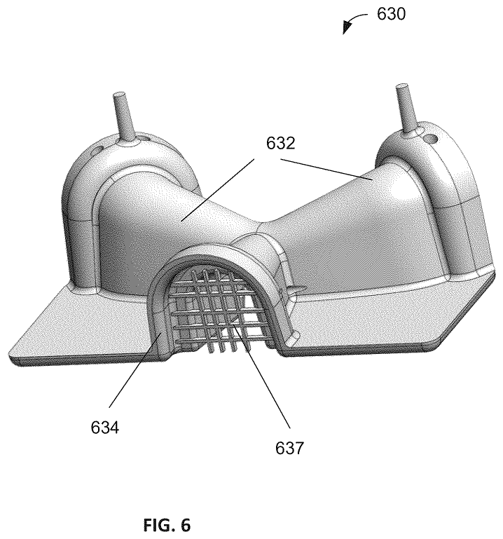

FIG. 6 shows another optional refinement of certain embodiments of the flow tunnel 630 according to the present invention. This embodiment employs a vortex breaker 637 at the exit port 634 of the flow tunnel 630. The vortex breaker 637 will reduce pressure losses at the exit port 634 and maximize the delay in the onset of air entrainment as the volume of liquid coolant fluid in the reservoir body drops. Still another optional refinement adds contouring of the flow path in the reservoir body itself, and not relying solely on the geometry and features of the flow tunnel to control the flow of liquid coolant fluid from reservoir inlet to reservoir outlet.

The above-described preferred embodiments are intended to illustrate the principles of the invention, but not to limit its scope. Various other embodiments, modifications and equivalents to these preferred embodiments may occur to those skilled in the art upon reading the present disclosure or practicing the claimed invention. Such variations, modifications and equivalents are intended to come within the scope of the invention and the appended claims.

What is claimed is:

1. A reservoir for a liquid cooling system, comprising:
(a) a reservoir body having an inlet and an outlet;
(b) a reservoir lid attached to the reservoir body;
(c) an internal chamber disposed between the reservoir body and the reservoir lid; and
(d) a flow tunnel disposed within the internal chamber, the flow tunnel comprising
(i) an entry port, fluidly coupled to the inlet on the reservoir,
(ii) an exit port fluidly coupled to the outlet on the reservoir,
(iii) an upper portion proximate to the entry port,
(iv) a lower portion proximate to the exit port,
(v) an active flow pattern region located between the upper portion and the lower portion and extending from the entry port to the exit port,
(vi) an active to passive flow communication channel located in the upper portion, and
(vii) a passive to active flow communication channel located in the lower portion,
(viii) wherein,
(A) the entry port is configured to receive liquid coolant fluid flowing into the inlet and transfer the liquid coolant fluid into the active flow pattern region,
(B) the active to passive flow communication channel on the upper portion is configured to cause at least some of the liquid cooling fluid flowing into the active flow pattern region via the entry port to pass out of the active flow pattern region and into a passive flow pattern region of the internal chamber of the reservoir, and
(C) the passive to active flow communication channel on the lower portion is configured to cause at least some of the liquid cooling fluid located inside the passive flow pattern region of the internal chamber to pass out of the passive flow pattern region of the internal chamber and back into the active flow pattern region of the flow tunnel.

2. The reservoir of claim 1, wherein the active flow pattern region defines a contoured flow path, and any liquid coolant fluid that flows through the active flow pattern region will travel along the contoured flow path.

3. The reservoir of claim 1, wherein the flow tunnel is permanently attached to the internal chamber of the reservoir.

4. The reservoir of claim 1, wherein the flow tunnel is removably attached to the internal chamber of the reservoir.

5. The reservoir of claim 1, further comprising a standoff pin on the upper portion configured to engage with a lid over the internal chamber of the reservoir to help stabilize the flow tunnel inside the internal chamber of the reservoir.

6. The reservoir of claim 1, wherein a descending pressure gradient is created in the active flow pattern region as a result of liquid coolant flowing along the flow tunnel, thereby causing a parallel flow path to develop with flow leaving the flow tunnel through the active to passive flow communication channels and returning to the flow tunnel through the passive to active flow communication channels.

7. The reservoir of claim 1, further comprising a set of vanes located inside the flow tunnel at a location where the flow tunnel has a sharp turn, the vanes assisting in reducing pressure drops associated with the liquid coolant fluid having to change direction while flowing through the sharp turn in the flow tunnel.

8. The reservoir of claim 1, further comprising a vortex breaker adjacent to the exit port to help reduce pressure drops and air entrainment at or near the exit port.

9. The reservoir of claim 1, wherein:
(a) the entry port is fluidly connected to the exit port by a set of inner walls extending from the entry port to the exit port of the flow tunnel;
(b) the active flow pattern region is located with a space defined by the inner walls of the flow tunnel; and
(c) the inner walls converge and then diverge between the entry port and the exit port.

10. The reservoir of claim 9, wherein:
(a) a junction is created where the set of inner walls connects the entry port to the exit port; and
(b) the passive to active flow communication channel is located at the junction.

11. The reservoir of claim 9, wherein the set of inner walls are contoured so that the liquid coolant fluid flows through a contoured path as the liquid coolant fluid flows through the active flow pattern region.

12. The reservoir of claim 1, wherein:
(a) the entry port is fluidly connected to the exit port by a set of inner walls extending from the entry port to the exit port of the flow tunnel;
(b) the active flow pattern region is located within a space defined by the inner walls of the flow tunnel; and
(c) the set of inner walls diverge as the liquid coolant fluid flows along the flow tunnel away from the entry port.

13. The reservoir of claim 1, wherein the flow tunnel further comprises:
(a) a second entry port fluidly coupled to a second inlet on the reservoir;
(b) a second upper portion proximate to the second entry port;
(c) a second active flow pattern region located between the second upper portion and the lower portion and extending from the second entry port to the exit port; and
(d) a second active to passive flow communication channel located in the second upper portion;
(e) wherein,
(i) the second entry port is configured to receive liquid coolant fluid flowing into the second inlet and transfer the liquid coolant fluid into the second active flow pattern region, and
(ii) the second active to passive flow communication channel on the second upper portion is configured to cause at least some of the liquid cooling fluid flowing into the second active flow pattern region via the second entry port to pass out of the second active flow pattern region and into the passive flow pattern region of the internal chamber of the reservoir.
